(19) United States
(12) Patent Application Publication
(10) Pub. No.: US 2026/0215266 A1
(43) Pub. Date: Jul. 23, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Chien-Chang Lin, New Taipei City (TW); Kris Lipu Chuang, Hsinchu City (TW); CHIH-TING LAI, Hsinchu City (TW)

(73) Assignee: Taiwan Semiconductor Manufacturing Company, Ltd., Hsinchu (TW)

(21) Appl. No.: 19/033,456

(22) Filed: Jan. 21, 2025

(51) Int. Cl. H01L 23/473; H01L 21/48; H01L 21/56; H01L 23/00; H01L 23/053; H01L 25/065; H10B 80/00

(52) U.S. Cl. CPC H10W 40/47; H10W 70/023; H10W 76/15; H10B 80/00; H10W 74/01; H10W 74/15; H10W 90/00; H10W 90/724; H10W 90/734

(57) ABSTRACT

A semiconductor package includes a substrate, a package structure disposed over the substrate, and a cover structure including a ring portion disposed over the substrate and laterally surrounding the package structure, a lid portion covering and thermally coupled to the package structure, and a fluid channel passing through the ring portion and laterally surrounding the package structure.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 4 illustrates a cross sectional views of intermediate stages in the manufacturing of a semiconductor package according to some embodiments of the present disclosure.

FIG. 5 illustrates a perspective top view of a semiconductor package according to some embodiments of the present disclosure.

FIG. 6 illustrates a perspective top view of a semiconductor package according to some embodiments of the present disclosure.

FIG. 7 illustrates a perspective top view of a semiconductor package according to some embodiments of the present disclosure.

FIG. 8 illustrates a cross sectional view of a cover structure of a semiconductor package according to some embodiments of the present disclosure.

FIG. 9 illustrates a cross sectional view of a cover structure of a semiconductor package according to some embodiments of the present disclosure.

FIG. 10 to FIG. 14 illustrates a cross sectional views of intermediate stages in the manufacturing of a semiconductor package according to some embodiments of the present disclosure.

FIG. 15 to FIG. 21 illustrates a cross sectional views of intermediate stages in the manufacturing of a semiconductor package according to some embodiments of the present disclosure.

FIG. 22 illustrates a cross sectional view of the semiconductor package according to some embodiments of the present disclosure.

FIG. 23 illustrates a cross sectional view of the semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments disclosed herein relate generally to packages with a cover structure surrounding and covering a package structure that is bonded to a substrate. The cover structure includes a fluid channel passing through the cover structure for cooling fluid to flow therein and an inlet and an outlet of the fluid channel are located on side surfaces of the cover structure. As such, the fluid channel can be integrated within the cover structure and laterally surrounds the package structure for heat dissipation. In addition, the pipes for providing and/or receiving the cooling fluid are coupled to the inlet and the outlet at the side surfaces of the cover structure without having to mount an additional fluid cooling device over the package structure. Accordingly, overall size of the semiconductor package can be further reduced so that a compact semiconductor package can be achieved. Moreover, the heat generated from the package structure can be dissipated through the cooling fluid in the fluid channel passing through the cover structure, so the heat dissipation efficiency of the semiconductor package can be improved. Furthermore, the fluid channel extending through the cover structure reduces the rigidity of the lid portion of the cover structure that is bonded to the package structure, so as to reduce the thermal stress between the cover structure and the package structure and improve the reliability of the semiconductor package.

The foregoing broadly outlines some aspects of the embodiments described herein. Some embodiments described herein are described in the context of 3D IC packages or 2.5D IC packages. Some variations of the exemplary methods and structures are described in the embodiments of the disclosure. A person having ordinary skill in the art will readily understand other modifications may be made that are contemplated within the scope of other embodiments. Although embodiments of the method may be described in a particular order, various other embodiments of the method may be performed in any logical order and may include fewer or more steps than what is described herein.

In one embodiment, the package structure may include a system on chip (SoC) package, a chip on wafer on substrate (CoWoS®) package, system on integrate chip (SoIC) package, or the like. The intermediate stages of forming the packages are illustrated in accordance with some embodiments. Some variations of some embodiments are discussed. Throughout the various views and illustrative embodiments, like reference numbers are used to designate like elements.

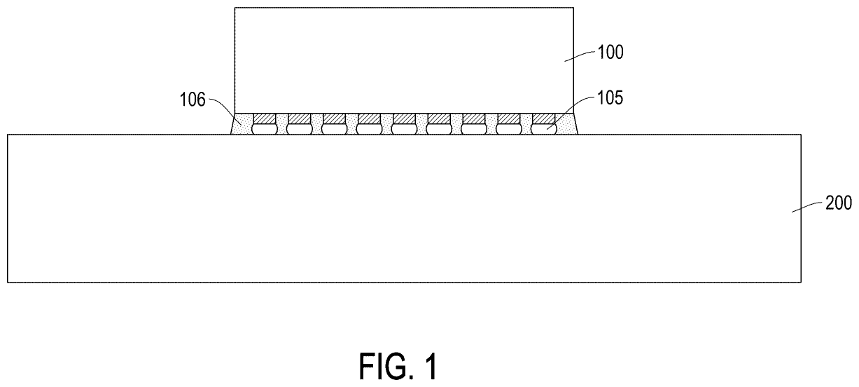

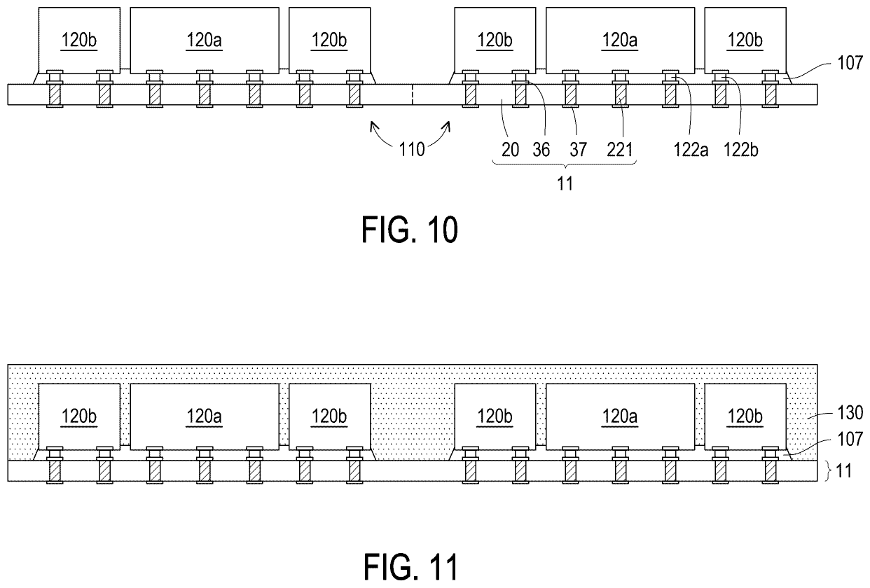

FIG. 1 to FIG. 4 illustrates a cross sectional views of intermediate stages in the manufacturing of a semiconductor package according to some embodiments of the present disclosure. Referring to FIG. 1, a package structure 100 is provided over a substrate 200. It is noted that the packager structure 100 is illustrated in an abstract form as a blank block shown in FIG. 1 to FIG. 7 for purpose of simplicity and convenience of illustration. Some exemplary embodiments of the possible package structures are illustrated and described, as examples, in more detail with reference of FIG. 10 to FIG. 21.

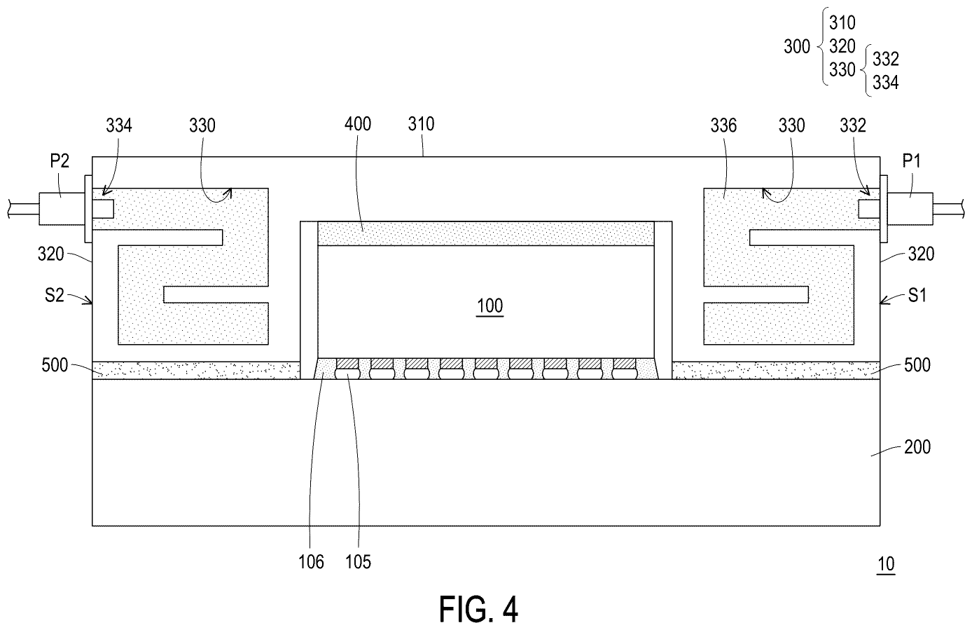

In some embodiments, the substrate 200 may include a dielectric core layer, build-up or laminated dielectric layers stacked over opposite surfaces of the dielectric core layer, conductive wiring layers embedded in the build-up or laminated dielectric layers, conductive vias penetrating through the dielectric core layer and the build-up or laminated dielectric layers. The substrate 200 may be a package substrate, which may be a printed circuit board (PCB) or the like. In some embodiments, the substrate 200 may include through-vias, active devices, passive devices, and the like. The substrate 200 may further include conductive pads formed at the upper and lower surfaces of the substrate 200, so that a plurality of conductive connectors (e.g. the conductive connectors 210 shown in FIG. 4) such as solder balls, can be bonded to the conductive pads at the lower surface of the substrate 200 opposite the package structure 100 to allow the substrate 200 to be mounted to another device.

The package structures 100 may be picked-up and placed on an upper surface of the substrate 200 through, for example, a pick and place tool. Then, the package structure 100 is bonded onto the substrate 200 through a plurality of conductive bumps 105. The conductive bumps 105 are aligned to, and are put against, the bond pads of the substrate 200. The conductive bumps 105 may be reflowed to create a bond between the package structure 100 and the substrate 200.

Then, after the package structure 100 is bonded over the substrate 200, an underfill 106 may be formed to fill a gap between the substrate 200 and the package structure 100. The conductive bumps 105 are laterally encapsulated and protected by the underfill 106 such that damage of the conductive bumps 105 resulted from CTE mismatch between the package structure 100 and the substrate 200 may be prevented. Accordingly, reliability of the conductive bumps 105 may be improved. In some embodiments, the underfill 106 not only fills the gap between the substrate 200 and the package structure 100, but also covers a part of the sidewalls of the package structure 100.

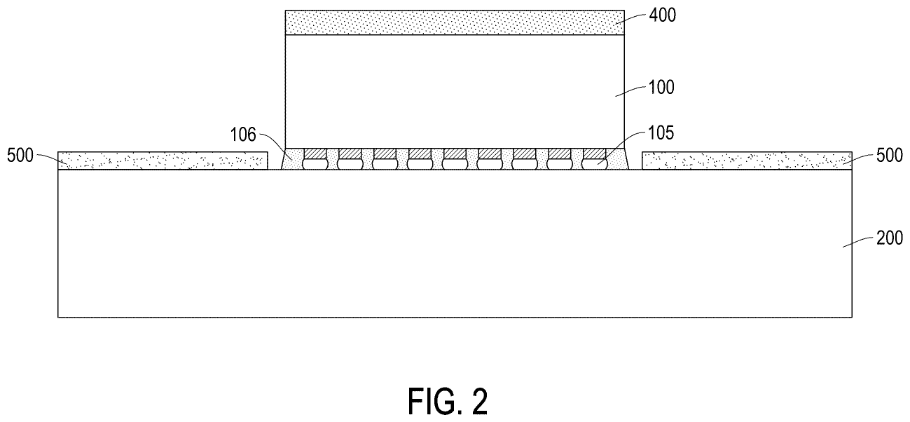

Then, referring to FIG. 2, a thermal interface material (TIM) 400 is provided over the package structure 100. In detail, the thermal interface material 400 is applied to cover a top surface of the package structure 100. In additional, an adhesive 500 is applied to a peripheral region of the substrate 200 that surrounds the package structure 100. In some embodiments, the material of the thermal interface material 400 may include metallic TIM, such as indium (In) sheet or film, indium foil, indium solder, silver (Ag) paste, silver alloy or combination thereof. For the embodiment of the thermal interface material 400 being metallic TIM, a backside metallization layer may be formed over the top surface of the package structure 100 for better bonding the metallic TIM. The material of the backside metallization layer may include copper (Cu), titanium (Ti), nickel-vanadium (NiV), nickel (Ni), silver (Ag), gold (Au), the like, or any combination thereof, with an overall thickness ranges from 0.6 μm to 0.65 μm.

In some embodiments, the thermal interface material 400 may also be polymer-based TIM with thermal conductive fillers. Applicable thermal conductive filler materials may include aluminum oxide, boron nitride, aluminum nitride, aluminum, copper, silver, indium, a combination thereof, or the like. The thermal interface material 400 may include film-based or sheet-based material such as sheet with synthesized carbon nano-tube (CNT) structure integrated into the sheet, thermal conductive sheet with vertically oriented graphite fillers or the like. The thermal interface material 400 may be formed of liquid metal or liquid pad or other metallic material or combination thereof. The material of the adhesive 500 may include thermally conductive adhesive or epoxy-based adhesive or the like.

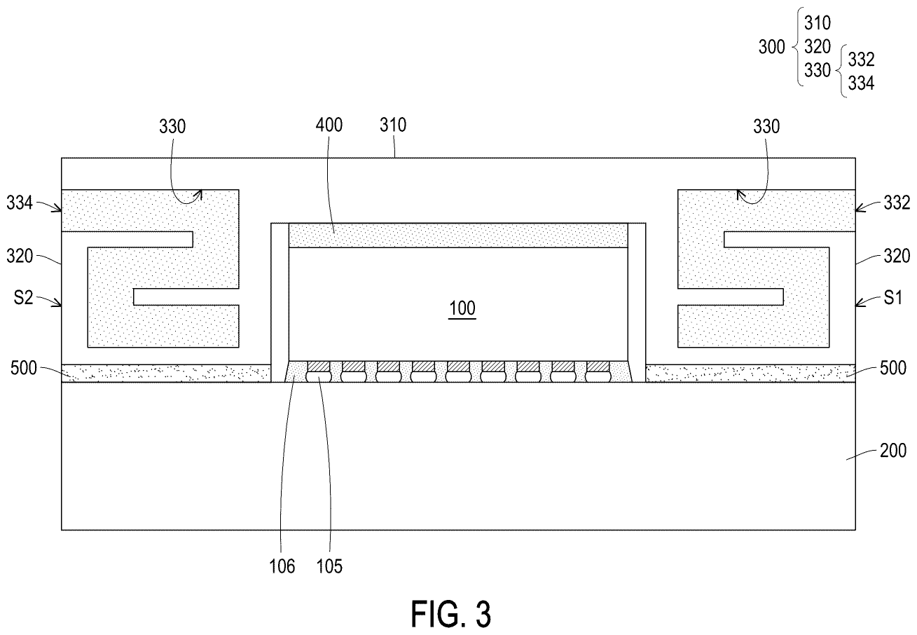

The adhesive 500 may be an epoxy, a silicon resin, a glue, or the like. The adhesive 500 may have a better adhering ability than the thermal interface material 400. The adhesive 500 may have a thermal conductivity from about 1 W/m·K to about 3 W/m·K, lower than about 0.5 W/m·K, or the like. The adhesive 500 may be positioned so as to allow a heat dissipating feature such as a cover structure 300 shown in FIG. 3 to be attached around the package structure 100. Thus, in some embodiments, the adhesive 500 may be disposed around the perimeter of, or even encircle, the package structure 100.

Then, referring to FIG. 3, the cover structure 300 is bonded over the substrate 200 through the adhesive 500, and in contact with the thermal interface material 400 to be thermally coupled to the package structure 100 through the thermal interface material 400. That is, the cover structure 300 is adhered to the top surface of the substrate 200 through the adhesive 500 and thermally coupled to the package structure 100 through the thermal interface material 400. The cover structure 300 may be formed from a material having a high thermal conductivity such as copper, aluminum, cobalt, copper coated with nickel, stainless steel, tungsten, silver diamond, aluminum silicon carbide, combinations thereof, or the like. Furthermore, the cover structure 300 may serve and function as a heat sink. In some embodiments, the cover structure 300 may be a metal coated with another metal, such as gold. The cover structure 300 may be formed of a material having a thermal conductivity from about 100 W/m·K to about 400 W/m·K, such as about 400 W/m. K. The cover structure 300 covers and surrounds the package structure 100. In some embodiments, the cover structure 300 is a single continuous material. In other embodiments, the cover structure 300 may include multiple pieces that may be the same or different materials.

In some embodiments, the cover structure 300 includes a lid portion 310, a ring portion 320 and at least one fluid channel 330. The ring portion 320 is disposed over the substrate 200 and laterally surrounds the package structure 100. The ring portion 320 is attached to the substrate 200 through the adhesive 500. The lid portion 310 covers the package structure 100 and is thermally coupled to the package structure 100 through the thermal interface material 400. In the present embodiment, the cover structure 300 is integrally formed. That is, there is no interface between the lid portion 310 and the ring portion 320. The fluid channel 330 passes through the ring portion 320 that laterally surrounds the package structure 100.

In some embodiments, the cover structure 300 further includes an inlet 332 and an outlet 334. The inlet 332 is in fluid communication with the fluid channel 330 for cooling fluid to flow into the fluid channel 330. The outlet 334 is in fluid communication with the fluid channel 330 for the cooling fluid to flow out of the fluid channel 330. It is noted that the location of the inlet 332 and the outlet 334 are merely for illustration. The disclosure is not limited thereto. In one embodiment, the inlet 332 and the outlet 334 are located on at least one vertical side surface of the cover structure 300. For example, the inlet 332 is located on a first outer side surface S1 of the cover structure 300. The outlet 334 is located on a second outer side surface S2 of the cover structure 300. In the present embodiment, the first outer side surface S1 and the second outer side surface S2 are opposite to each other. That is, the inlet 332 and the outlet 334 are located on two opposite side surfaces of the cover structure 300. In some embodiments, the inlet 332 and the outlet 334 are located at an upper portion of the vertical side surface S1, S2 of the ring portion 320, which is away from the substrate 200, and extended toward a lower portion of the ring portion 320, which is closer to the substrate 200. As it is shown in FIG. 3, the fluid channel 330 is extended from an upper portion of the side wall (i.e., ring portion 320) of the cover structure 300 to a lower portion of the side wall (i.e., ring portion 320) in a zigzag manner, and the fluid channel 330 may then be extended from the lower portion of the ring portion 320 toward the upper portion of the ring portion 320 in a zigzag manner. The configuration of the zigzag layout of the fluid channel 330 increases length of the circling path and contact area between the cooling fluid and the ring portion 320 (i.e., inner walls of the fluid channel 330), so as to improve the heat exchange and heat dissipation efficiency.

Then, referring to FIG. 4, in some embodiments, a first pipe P1 is connected to the inlet 332 for providing cooling fluid 336 from the first pipe P1 to the fluid channel 330, and a second pipe P2 is connected to the outlet 334 for the cooling fluid 336 in the fluid channel 330 to flow out of the fluid channel 330 and flow to the second pipe P2. The cooling fluid 336 may include fluid or liquid. As an example, the cooling fluid 336 includes fluid, such as oil, dielectric oil, water, a mixture of water and an anti-freezing agent, potassium formate, perfluorinate coolant, or the like. As a particular example, the cooling fluid 336 may include a non-electrically conductive liquid perfluorinate coolant, or the like. In some embodiments, the cooling fluid 336 may include two-phase liquid, such as any two-phase liquid commercially available from various manufacturers. One skilled in the art will understand that cooling fluid 336 may be any fluid capable of absorbing and releasing energy and may be in a fluid form, such as water, gas, oil, or a mixture thereof.

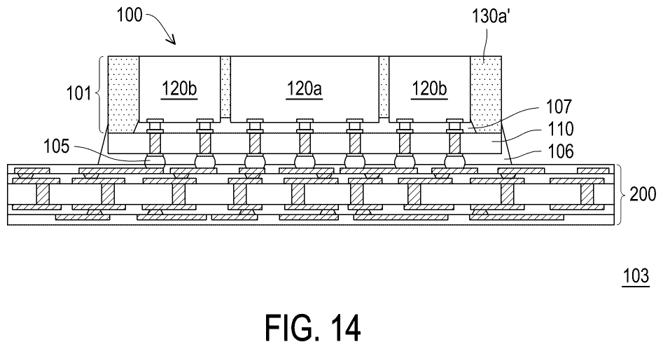

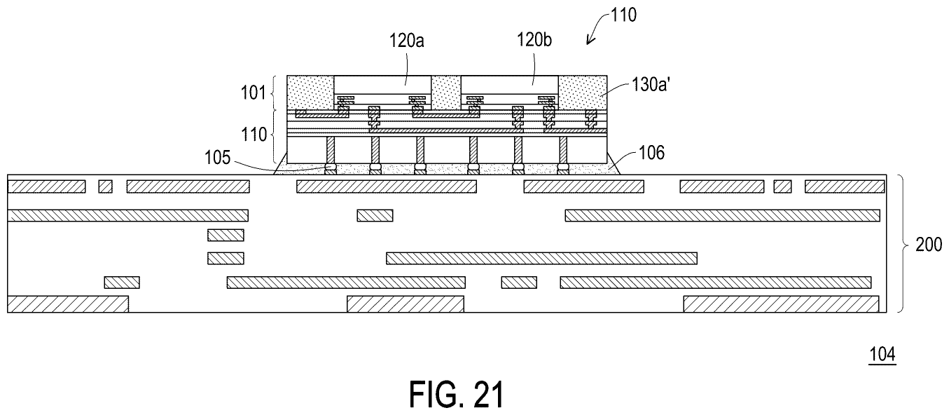

In some embodiments, the first pipe P1 and the second pipe P2 may be coupled to a reservoir (not shown) for storing cooling fluid 336 therein. Accordingly, the cooling fluid 336 flow into the fluid channel 330 through the first pipe P1 and the inlet 332. The cooling fluid 336 then circling through the cover structure 300 via the fluid channel 330 to help cool the device dies (e.g., the device dies 120a, 120b in FIG. 14 and FIG. 21) in the package structure 100. For example, the lid portion 310 thermally coupled to the package structure 100 absorbing the heat generated by operating the device dies and the heat is drawn away from the device dies to the ring portion 320 of the cover structure 300 where the heat is then dissipated to the ambient air and cools down by the cooling fluid 336 in the fluid channel 330. To further dissipate heat and enhance the cooling of cover structure 300, in another embodiment, a heat sink (not shown) may be thermally coupled to the cover structure 300 (or thermally coupled to the reservoir where the cooling fluid 336 is recycled back to), so that the heat sink can draw heat from the cooling fluid 336 in the cover structure 300 (or the cooling fluid 336 in the reservoir) to ambient air thereby cooling the cooling fluid 336.

Then, a plurality of conductive connectors 210 are then formed over a lower surface of the substrate 200. Each of the conductive connectors 210 may be electrically connected to one of the contact pads (not shown) of the substrate 200. The conductive connectors 210 enable electrical connection between the semiconductor package 10 and an external electronic device such as a PCB (not shown). The conductive connectors 210 may be or include solder bumps such as tin-containing solder bumps. The tin-containing solder bumps may further include copper, silver, gold, aluminum, lead, one or more other suitable materials, or a combination thereof. In some embodiments, the tin-containing solder bump is lead-free.

In some embodiments, solder balls (or solder elements) are disposed on the contact pads on the lower surface of the substrate 200. A reflow process is then carried out to melt the solder balls into the conductive connectors 210. In some other embodiments, under bump metallization (UBM) elements are formed over the exposed contact pads before the solder balls are disposed. In some other embodiments, solder elements are electroplated onto the exposed contact pads. Afterwards, a reflow process is used to melt the solder element to form the conductive connectors 210. Accordingly, the semiconductor package 10 shown in FIG. 4 is substantially formed.

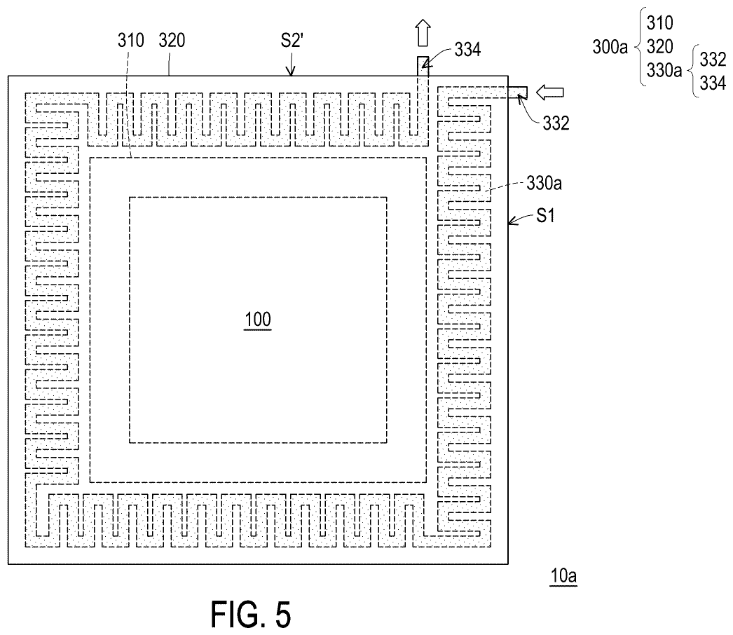

FIG. 5 illustrates a perspective top view of a semiconductor package according to some embodiments of the present disclosure. It is noted that the semiconductor package shown in FIG. 5 contains many features same as or similar to the semiconductor package disclosed in the previous embodiments. For purpose of clarity and simplicity, detail description of same or similar features may be omitted, and the same or similar reference numbers denote the same or like components.

Referring to FIG. 5, in accordance with some embodiments of the disclosure, the inlet 332 is located on a first outer side surface S1 of the cover structure 300a, and the outlet is located on a second outer side surface S2′ of the cover structure 300a. In this embodiment, the first outer side surface S1 and the second outer side surface S2′ are adjacent to each other. That is, the inlet 332 and the outlet 334 are located on two adjacent side surfaces of the cover structure 300a. As shown in FIG. 5, the fluid channel 330a does not overlap with the package structure 100 from a top view, so that the thickness of the lid portion 310 that is thermally coupled to the package structure 100 can be reduced, so as to reduce the overall thickness of the semiconductor package. As it is shown in FIG. 4 and FIG. 5, the fluid channel 330a may be distributed in a zigzag manner along a length direction, a width direction and/or a thickness direction of the ring portion 320 of the cover structure 300a. The configuration of the zigzag layout of the fluid channel 330a increases length of the circling path and contact area between the cooling fluid and the ring portion 320 (i.e., inner walls of the fluid channel 330a), so as to improve the heat exchange and heat dissipation efficiency.

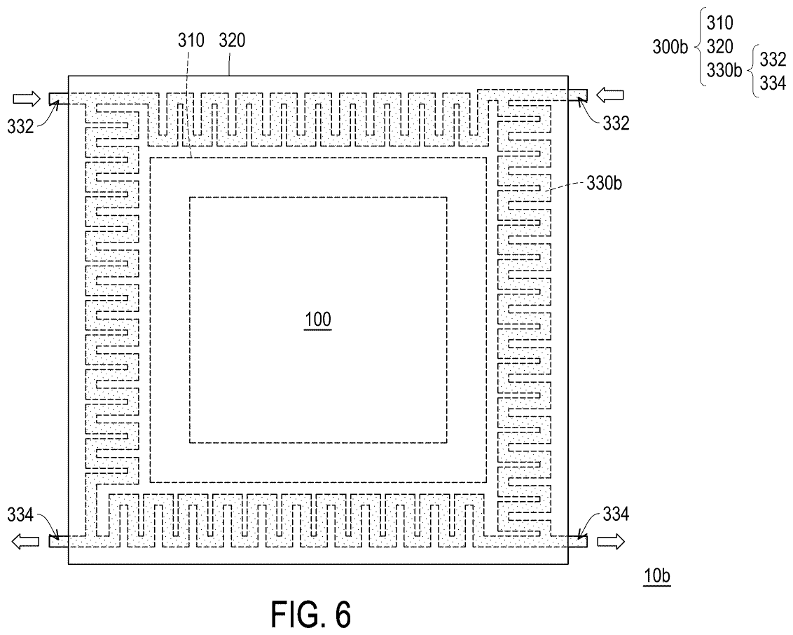

FIG. 6 illustrates a perspective top view of a semiconductor package according to some embodiments of the present disclosure. It is noted that the semiconductor package shown in FIG. 6 contains many features same as or similar to the semiconductor package disclosed in the previous embodiments. For purpose of clarity and simplicity, detail description of same or similar features may be omitted, and the same or similar reference numbers denote the same or like components.

Referring to FIG. 6, in accordance with some embodiments of the disclosure, the cover structure 300b includes a plurality of inlets 332 (two inlets 332 are illustrated, but not limited thereto) and a plurality of outlets 334 (two outlets 334 are illustrated, but not limited thereto), which are in fluid communication with the fluid channel 330b. In some embodiments, the inlets 332 and the outlets 334 are all in fluid communication with a single loop of the fluid channel 330b. In other embodiments, the cover structure 300b may include a plurality of fluid channels 330b, and each of the fluid channels 330b is in fluid communication with one of the inlets 332 and one of the outlets 334. In the present embodiment, the inlets 332 are disposed on two opposite side surfaces of the cover structure 300b, and one of the inlets 332 and one of the outlets 334 are disposed on the same side surface of the cover structure 300b, but the disclosure is not limited thereto. As shown in FIG. 6, the fluid channel 330b does not overlap with the package structure 100 from a top view, so that the thickness of the lid portion 310 that is thermally coupled to the package structure 100 can be reduced, so as to reduce the overall thickness of the semiconductor package. As it is shown in FIG. 4 and FIG. 6, the fluid channel 330b may be distributed in a zigzag manner along a length direction, a width direction and/or a thickness direction of the ring portion 320 of the cover structure 300b. The configuration of the zigzag layout of the fluid channel 330b increases length of the circling path and contact area between the cooling fluid and the ring portion 320 (i.e., inner walls of the fluid channel 330b), so as to improve the heat exchange and heat dissipation efficiency.

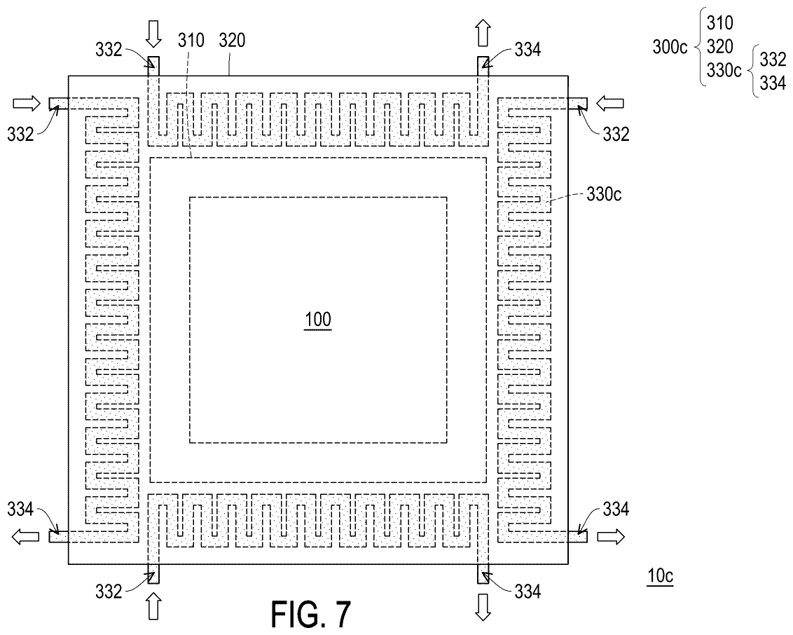

FIG. 7 illustrates a perspective top view of a semiconductor package according to some embodiments of the present disclosure. It is noted that the semiconductor package shown in FIG. 7 contains many features same as or similar to the semiconductor package disclosed in the previous embodiments. For purpose of clarity and simplicity, detail description of same or similar features may be omitted, and the same or similar reference numbers denote the same or like components.

Referring to FIG. 7, in accordance with some embodiments of the disclosure, the cover structure 300c includes a plurality of inlets 332 (four inlets 332 are illustrated, but not limited thereto) and a plurality of outlets 334 (four outlets 334 are illustrated, but not limited thereto), which are in fluid communication with the fluid channel 330c. In the embodiment, the cover structure 300c may include a plurality of fluid channels 330c, and each of the fluid channels 330c is in fluid communication with one of the inlets 332 and one of the outlets 334. In the embodiment, a set of inlet 332 and outlet 334 (including one of the inlets 332 and one of the outlets 334 in fluid communication with respective one of the fluid channels 330c) are disposed at the same side surface of the cover structure 300c, but the disclosure is not limited thereto. In other embodiments, the inlets 332 and the outlets 334 may all be in fluid communication with a single loop of the fluid channel. As shown in FIG. 7, the fluid channel 330c does not overlap with the package structure 100 from a top view, so that the thickness of the lid portion 310 that is thermally coupled to the package structure 100 can be reduced, so as to reduce the overall thickness of the semiconductor package. As it is shown in FIG. 4 and FIG. 7, the fluid channel 330c may be distributed in a zigzag manner along a length direction, a width direction and/or a thickness direction of the ring portion 320 of the cover structure 300c. The configuration of the zigzag layout of the fluid channel 330c increases length of the circling path and contact area between the cooling fluid and the ring portion 320 (i.e., inner walls of the fluid channel 330c), so as to improve the heat exchange and heat dissipation efficiency.

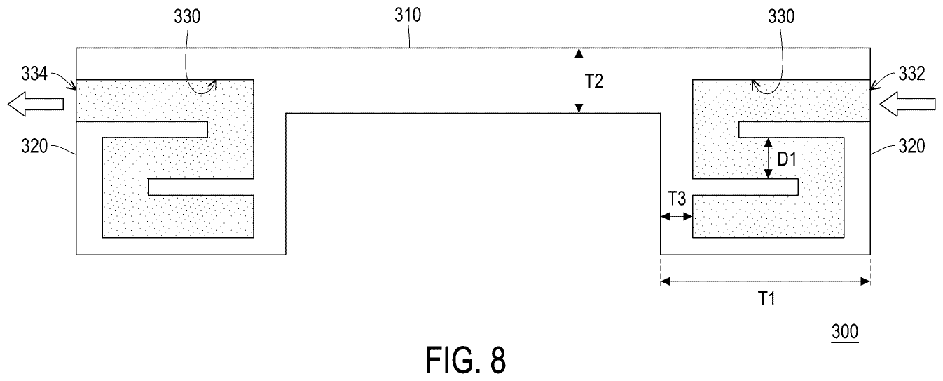

FIG. 8 illustrates a cross sectional view of a cover structure of a semiconductor package according to some embodiments of the present disclosure. Referring to FIG. 8, in accordance with some embodiments of the disclosure, certain range of sizes of the cover structure 300 may be designated to further enhance the heat dissipation efficiency and reliability of the semiconductor package. For example, a thickness T1 of the side wall (i.e., the ring portion 320) of the cover structure 300 is substantially equal to or greater than about 8 mm. If the thickness T1 of the ring portion 320 is smaller than 8 mm, the cover structure 300 may not have enough mechanical strength, and the fluid channel 330 extended through the ring portion 320 may not have enough length to perform heat exchange, which would affect the heat dissipation efficiency of the semiconductor package. A thickness T2 of the lid portion 310 is substantially equal to or greater than about 2 mm, and may be substantially equal to or smaller than about 8 mm. If the thickness T2 of the lid portion 310 is smaller than 2 mm, the lid portion 310 may not have enough mechanical strength, and the heat dissipation efficiency of the semiconductor package may also be reduced. If the thickness T2 of the lid portion 310 is greater than 8 mm, the overall thickness of the semiconductor package may not meet the compact requirement, and the lid portion 310 may be too stiff, which would increase the thermal stress between the lid portion 310 and the package structure and result in delamination. A thickness T3 of the side wall of the fluid channel 330 is substantially equal to or greater than about 1 mm. If the thickness T3 is smaller than 1 mm, the ring portion 320 may not have enough mechanical strength. In the embodiment, a diameter D1 of the fluid channel 330 is substantially equal to or greater than about 100 μm and substantially equal to or smaller than about 1 mm.

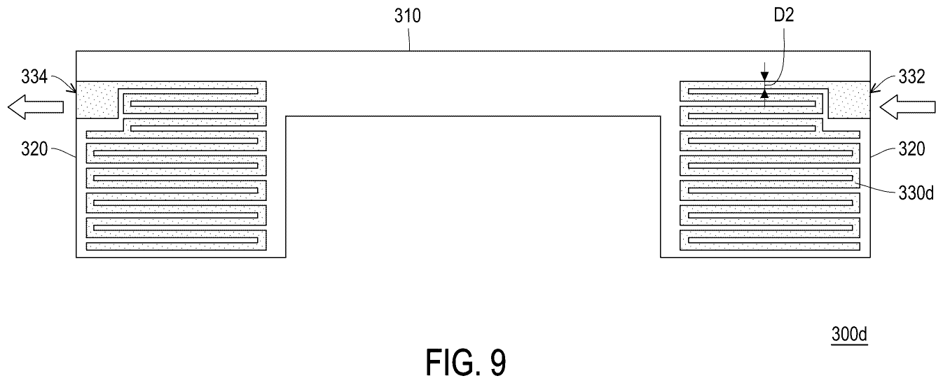

FIG. 9 illustrates a cross sectional view of a cover structure of a semiconductor package according to some embodiments of the present disclosure. It is noted that the semiconductor package shown in FIG. 9 contains many features same as or similar to the semiconductor package disclosed in the previous embodiments. For purpose of clarity and simplicity, detail description of same or similar features may be omitted, and the same or similar reference numbers denote the same or like components.

Referring to FIG. 9, in accordance with some embodiments of the disclosure, microchannel may be applied to the fluid channel 330d. That is, the diameter D2 of the fluid channel 330d is below about 1 mm. In the present embodiment, the diameter D2 of the fluid channel 330d is substantially equal to or greater than about 100 nm and substantially smaller than about 1 mm. The micro fluid channel 330d provides high surface area to volume ratio, so that the heat dissipation efficiency of the semiconductor package can be significantly improved. On the other hand, the fluid channel 330 with slightly greater diameter D1 provides the benefits of lower manufacturing costs and requiring lower pumping power for pumping the cooling fluid into the fluid channel 330.

FIG. 10 to FIG. 14 illustrates a cross sectional views of intermediate stages in the manufacturing of a semiconductor package according to some embodiments of the present disclosure. FIG. 10 to FIG. 14 illustrate manufacturing process of one of the possible package structures that may be incorporated into the semiconductor package described above. In accordance with some embodiments of the disclosure, configurations of cover structure in the disclosure can be applied in a semiconductor package such as a Chip on Wafer on Substrate (CoWoS®) as it is shown below, but the disclosure is not limited thereto.

Referring to FIG. 10, an interconnect structure (e.g., an interposer wafer) 11 including a plurality of interconnect structures 110 arranged in array is provided. The interposer wafer 11 may be a silicon interposer wafer including multiple silicon interposers or other suitable semiconductor interposer wafer. The interposer wafer 11 may include a substrate 20, bump pads 36 disposed on an upper surface of the substrate 20, bump pads 36 disposed on a lower surface of the substrate 20, and through semiconductor vias (TSVs) 21 penetrating through the substrate 20, wherein the bump pads 36 are electrically connected to the bump pads 37 through the TSVs 21. The interposer wafer 11 may be a semiconductor substrate such as a silicon substrate. The interposer wafer 11 may also be formed of another semiconductor material such as silicon germanium, silicon carbon, or the like. In accordance with some embodiments, active devices such as transistors (not separately illustrated) are formed at a surface of the interposer wafer 11. Passive devices (not separately illustrated) such as resistors and/or capacitors may also be formed in the interposer wafer 11. In accordance with alternative embodiments of the present disclosure, the interposer wafer 11 may be a semiconductor substrate or a dielectric substrate, and the respective interposer wafer 11 may not include active devices therein. In accordance with these embodiments, the interposer wafer 11 may, or may not, include passive devices formed therein.

The TSVs 21 may be formed to extend from the top surface of the interposer wafer 11 into the interposer wafer 11. The TSVs 21 may be referred to as through-substrate vias or through-silicon vias in embodiments in which the interposer wafer 11 is a silicon substrate. In some embodiments, the interposer wafer 11 may include an interconnect structure (not separately illustrated) formed over the substrate 20 which is used to electrically connect to the integrated circuit devices, if any, and the TSVs 21. The interconnect structure may include a plurality of dielectric layers, metal lines formed in the dielectric layers, and vias formed between, and interconnecting, the overlying and underlying metal lines. In accordance with some embodiments, the dielectric layers may be formed of silicon oxide, silicon nitride, silicon carbide, silicon oxynitride, combinations thereof, and/or multi-layers thereof. Alternatively, the dielectric layers may include one or more low-k dielectric layers having low dielectric constants (k values). The k values of the low-k dielectric materials in the dielectric layers may be lower than about 3.0 or lower than about 2.5, for example.

At least one device die is provided over and boned to a surface of the interconnect structure (i.e. the interposer wafer 11). In the embodiment, device dies 120a and device dies 120b are illustrated herein, but not limited thereto. The device dies 120a and device dies 120b are electrically connected to the interconnect structures 110 of the interposer wafer 11. In some embodiments, the device dies 120a and device dies 120b are electrically connected to the bump pads 36 of the interposer wafer 11 through conductive bumps 122a and conductive bumps 122b. The conductive bumps 122a are located between the device dies 120a and the bump pads 36, and the conductive bumps 122b are located between the device dies 120b and the bump pads 36. In some embodiments, the conductive bumps 122a may be formed on the device dies 120a before the device dies 120a are mounted on the interposer wafer 11, and the conductive bumps 122b may be formed on the device dies 120b before the device dies 120b are mounted on the interposer wafer 11. The conductive bumps 122a may be formed through a wafer-level bumping process performed on semiconductor wafers including the device dies 120a arranged in array, and the conductive bumps 122b may be formed through another wafer-level bumping process performed on semiconductor wafers including the device dies 120b arranged in array. In some embodiments, the device dies 120a includes logic dies, System-on-Chip (SoC) dies or other suitable device dies, and the device dies 120b includes High Bandwidth Memory (HBM) cubes each having stacked memory dies or other suitable device dies.

In some embodiments, the device dies 120a may include a high-power consuming die disposed between two device dies 120b, which may be a low-power consuming dies. The high-power consuming die and the low-power consuming dies may be die stacks and may be referred to as chips. The high-power consuming die consumes a relatively high amount of power and, therefore, generates a relatively large amount of heat compared to the lower-power consuming dies. The high-power consuming die may be a processor, such as a central processing unit (CPU), a graphics processing unit (GPU), or the like. The low-power consuming dies may be memory dies such as high bandwidth memory (HBM), memory cubes, memory stacks, or the like. While the present embodiment illustrates one high-power consuming die (e.g., device dies 120a) and two low-power consuming dies (e.g., device dies 120b) in a package, other embodiments may include any number of high-power consuming dies and/or low-power consuming dies.

In some embodiments, the conductive bumps 122a and the conductive bumps 122b include micro bumps. The conductive bumps 122a and the conductive bumps 122b may each include a copper (Cu) pillar covered by a nickel (Ni) cap, and the nickel (Ni) cap may be electrically connected to the bump pads 36 through solder material. For example, the solder material includes Sn—Ag solder material or other suitable solder material.

After the device dies 120a and the device dies 120b are mounted on and electrically connected to the interposer wafer 11 through the conductive bumps 122a and the conductive bumps 122b, underfills 107 are formed over the interposer wafer 11 to fill gaps between the device dies 120a and the interposer wafer 11 as well as gaps between the device dies 120b and the interposer wafer 11. The conductive bumps 122a and the conductive bumps 122b are laterally encapsulated and protected by the underfills 107 such that damage of the conductive bumps 122a and the conductive bumps 122b resulted from coefficient of thermal expansion (CTE) mismatch between the interposer wafer 11 and the device dies 120a and 120b may be prevented. Accordingly, reliability of the conductive bumps 122a and the conductive bumps 122b may be improved.

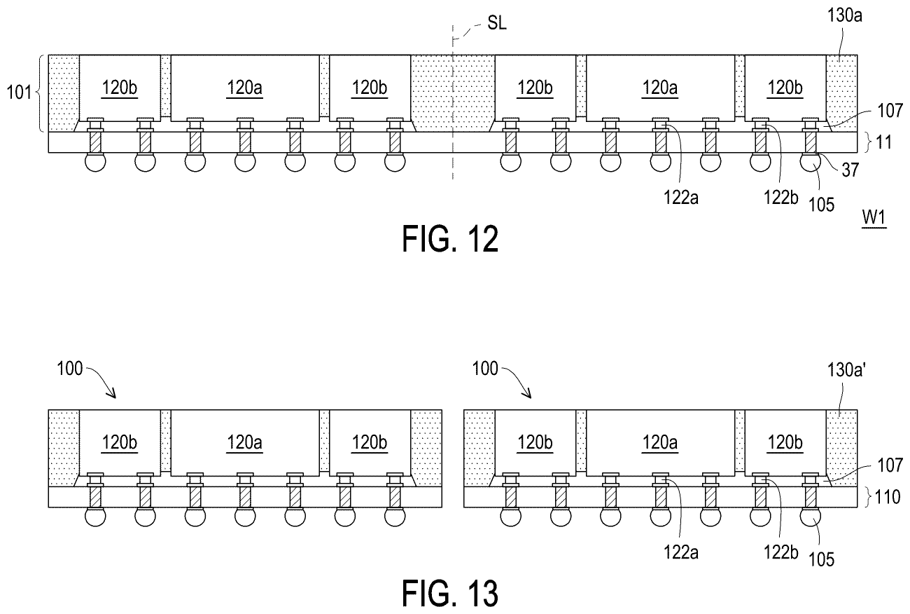

Referring to FIG. 11 and FIG. 12, the device dies 120a and 120b are encapsulated with an encapsulating material 130. The encapsulating material 130 is formed over the interposer wafer 11 to cover the device dies 120a and the device dies 120b. The encapsulating material 130 may be formed by an over-molding process or a deposition process followed by a removal process. In some embodiments, an encapsulating material 130 such as epoxy resin is formed on the interposer wafer 11 to cover the back surfaces and sidewalls of the device dies 120a and 120b through an over-molding process, and a grinding process, a chemical mechanical polishing (CMP) process or other suitable removal process is then performed to remove portions of the epoxy resin until the back surfaces of the device dies 120a and 120b are revealed. In some alternative embodiments, an encapsulating material 130 such as tetraethoxysilane (TEOS) formed oxide is formed on the interposer wafer 11 to cover back surfaces and sidewalls of the device dies 120a and 120b through a chemical vapor deposition (CVD) process, and a grinding process, a CMP process or other suitable removal process is then performed to remove portions of the TEOS formed oxide until the back surfaces of the device dies 120a and 120b are revealed. After performing the above-mentioned removal process, as illustrated in FIG. 12, an encapsulating material 130a is formed to laterally encapsulate the device dies 120a and 120b, and the top surface of the encapsulating material 130a is substantially leveled with the back surfaces of the device dies 120a and 120b.

In some embodiments, during the removal process of the encapsulating material 130, the encapsulating material 130, the device dies 120a and the device dies 120b are partially removed such that the thickness of the device dies 120a and 120b is reduced. At this point, an encapsulated semiconductor device 101 as shown in FIG. 12 that includes the device dies 120a and 120b laterally encapsulated by the encapsulating material 130a is formed. The encapsulated semiconductor device 101 is bonded over the interposer wafer 11.

A wafer-level bumping process may be performed such that conductive bumps 105 are formed over bump pads 37 of the interposer wafer 11. In some embodiments, the wafer-level bumping process for forming the conductive bumps 105 is performed before formation of the encapsulating material 130a. In some alternative embodiments, the wafer-level bumping process for forming the conductive bumps 105 is performed after formation of the encapsulating material 130a.

After forming the encapsulating material 130a and the conductive bumps 105, a reconstructed wafer W1 including the interposer wafer 11, the device dies 120a, the device dies 120b, the underfills 107, the encapsulating material 130a, and the conductive bumps 105 is formed.

Referring to FIG. 12 and FIG. 13, a wafer saw process is then performed along scribe lines SL such that the reconstructed wafer W1 is singulated into a plurality of package structures 100. The package structures 100 may each include an interconnect structure 110, an encapsulated semiconductor device 101 including at least one device die(s) 120a, 120b encapsulated by the encapsulating material 130a′ and bonded over the interconnect structure 110, a plurality of conductive bumps 122a, 122b, an underfill 107, and a plurality of conductive bumps 105. The conductive bumps 122a are electrically connected between the device die 120a and the interconnect structure 110. The conductive bumps 122b are electrically connected between the device die 120b and the interconnect structure 110. The underfill 107 laterally encapsulates the conductive bumps 122a and 122b. The underfill 107 may further cover sidewalls of the device dies 120a and 120b. The encapsulating material 130a′ laterally encapsulates the device dies 120a and 120b, wherein sidewalls of the encapsulating material 130a′ are substantially aligned with sidewalls of the interconnect structure 110. Furthermore, the conductive bumps 122a and 122b are disposed on a surface (e.g., an upper surface) of the interconnect structure 110, and the conductive bumps 105 are disposed on another surface (e.g., a lower surface) of the interconnect structure 110.

Referring to FIG. 14, a substrate 200 is provided. In some embodiments, the substrate 200 includes a dielectric core layer, build-up or laminated dielectric layers stacked over opposite surfaces of the dielectric core layer, conductive wiring layers embedded in the build-up or laminated dielectric layers, conductive vias penetrating through the dielectric core layer and the build-up or laminated dielectric layers. The substrate 200 may be a package substrate, which may be a printed circuit board (PCB) or the like. In some embodiments, the substrate 200 may include through-vias, active devices, passive devices, and the like. The substrate 200 may further include conductive pads formed at the upper and lower surfaces of the substrate 200, such that a plurality of conductive connectors (e.g. the conductive connectors 210 shown in FIG. 4) may be coupled to conductive pads at the lower surface of the substrate 200.

Then, at least one of the package structures 100 singulated from the reconstructed wafer W1 illustrated in FIG. 12 and FIG. 13 may be picked-up and placed on an upper surface of the substrate 200. The package structure 100 is electrically connected to the conductive wirings of the substrate 200 through the conductive bumps 105. After the package structure 100 is bonded over the substrate 200, an underfill 106 may be formed to fill a gap between the substrate 200 and the interconnect structure 110 of the package structure 100. The conductive bumps 105 are laterally encapsulated and protected by the underfill 106 such that damage of the conductive bumps 105 resulted from CTE mismatch between the interconnect structure 110 and the substrate 200 may be prevented. Accordingly, reliability of the conductive bumps 105 may be improved.

In some embodiments, the underfill 106 not only fills the gap between the substrate 200 and the interconnect structure 110 of the package structure 100, but also covers sidewalls of the package structure 100. As illustrated in FIG. 14, the underfill 106 not only fills the gap between the substrate 200 and the interconnect structure 110 of the package structure 100, but also covers sidewalls of the interconnect structure 110 and sidewalls of the encapsulating material 130a′.

After the package structure 100 is bonded over the substrate 200, a chip on wafer on substrate (CoWoS®) package 103 is formed. The package 103 includes a substrate 200, an interconnect structure 110 bonded over and electrically connected to the substrate 200, device dies 120a, 120b disposed on and electrically connected to the interconnect structure 110, an encapsulating material 130a′ disposed on the interconnect structure 110. The device dies 120a, 120b are laterally encapsulated by the encapsulating material 130a′. In some embodiments, the package 103 further includes an underfill 106 disposed between the interconnect structure 110 and the substrate 200. Then, the processes as illustrated in FIG. 3 to FIG. 4 can be applied to the package 103 herein and form the semiconductor package.

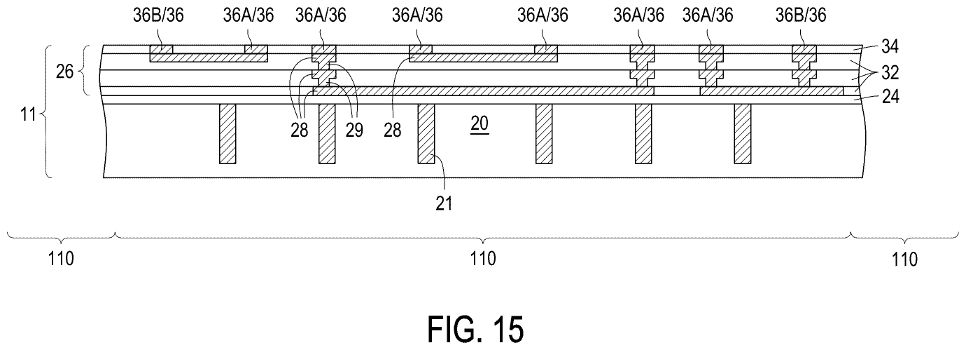

FIG. 15 to FIG. 21 illustrates a cross sectional views of intermediate stages in the manufacturing of a semiconductor package according to some embodiments of the present disclosure. It is noted that manufacturing method and structure of the semiconductor package shown in FIG. 15 to FIG. 21 contains many features same as or similar to the manufacturing methods and structures of the semiconductor packages disclosed in the previous embodiments. For purpose of clarity and simplicity, detail description of same or similar features may be omitted, and the same or similar reference numbers denote the same or like components.

In accordance with some embodiments of the disclosure, configurations of cover structure in the disclosure not only can be applied in a semiconductor package such as a Chip on Wafer on Substrate (CoWoS®) as it is shown above, but also can be applied to other suitable packages that suffers poor heat dissipation efficiency and bulk volume of the packages. FIG. 15 to FIG. 21 illustrate one of the possible packages such as a System on Integrate Chip (SoIC) package that can also be adopted in such configurations.

Referring to FIG. 15, a wafer 11 as shown in FIG. 15 is provided. In accordance with some embodiments of the present disclosure, the wafer 11 is an interposer wafer, which is free from any active devices such as transistors and/or diodes therein. In accordance with some embodiments of the present disclosure, the interposer wafer 11 is also free from passive devices such as capacitors, inductors, resistors, or the like therein. In some embodiments, the interposer wafer 11 may include a plurality of metal lines and vias therein, with some details of one of a plurality of interposer dies (interconnect structure) 110 illustrated schematically. The interposer dies 110 are alternatively referred to as interposers or chips hereinafter. The interposer dies 110 are used for routing, as will be discussed in subsequent paragraphs.

The wafer 11 may include a substrate 20 and the features over the top surface of the substrate 20. In accordance with some embodiments of the present disclosure, the substrate 20 is a semiconductor substrate. The substrate 20 may be formed of crystalline silicon, crystalline germanium, crystalline silicon germanium, and/or a III-V compound semiconductor such as GaAsP, AlInAs, AlGaAs, GaInAs, GaInP, GaInAsP, or the like. The semiconductor substrate 20 may also be a bulk silicon substrate or a silicon-on-insulator (SOI) substrate. In accordance with some embodiments in which the substrate 20 is a semiconductor substrate, shallow trench isolation (STI) regions (not shown) may be formed in the substrate 20 to isolate the regions in the substrate 20. In accordance with alternative embodiments, STI regions are not formed in the wafer 11 since the wafer 11 does not have active devices, and hence does not need STI regions to isolation active regions from each other. The substrate 20 may also be a dielectric substrate, which may be formed of silicon oxide, for example. In accordance with some embodiments, the wafer 11 may be a device wafer, which includes a plurality of device dies 110 therein. In accordance with some embodiments, the device dies 110 include active circuits, which include active devices such as transistors (not shown) formed at the top surface of the semiconductor substrate 20.

In accordance with some embodiments, a plurality of through vias 21 are formed to extend into the semiconductor substrate 20, wherein the through-vias are used to electrically inter-couple the features on opposite sides of the semiconductor substrate 20. The through vias 21 are also sometimes referred to as through substrate vias or through silicon vias when substrate 20 is a silicon substrate. The through vias 21 may be formed by forming recesses in the substrate 20 by, for example, etching, milling, laser techniques, a combination thereof, and/or the like. A thin dielectric material may be formed in the recesses, such as by using an oxidation technique. A thin barrier layer may be conformally deposited over the front side of the substrate 20 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 20 by, for example, CMP. Thus, the through vias 21 may include a conductive material and a thin barrier layer between the conductive material and the substrate 20. In accordance with alternative embodiments, no through-vias are formed extending into the semiconductor substrate 20.

In accordance with some embodiments, at least one dielectric layer 24 may be formed over the substrate 20. In accordance with some embodiments of the present disclosure, the dielectric layer 24 is an Inter-Layer Dielectric (ILD), which may be formed of silicon oxide, Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS), or the like. The dielectric layer 24 may be formed using thermal oxidation, spin coating, Flowable Chemical Vapor Deposition (FCVD), Atomic Layer Deposition (ALD), Chemical Vapor Deposition (CVD), Plasma Enhanced Chemical Vapor Deposition (PECVD), Low Pressure Chemical Vapor Deposition (LPCVD), or the like.

Over the dielectric layer 24 resides interconnect structure 26. Interconnect structure 26 includes metal lines 28 and vias 29, which are formed in the dielectric layers 32. The dielectric layers 32 are alternatively referred to as Inter-Metal Dielectric (IMD) layers hereinafter. In accordance with some embodiments of the present disclosure, the dielectric layers 32 are formed of low-k dielectric materials having dielectric constants (k-values) lower than 3.8. For example, the k values of the dielectric layers 32 may be lower about 3.0 or lower than about 2.5. The dielectric layers 32 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of the dielectric layers 32 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of the dielectric layers 32 includes depositing a porogen-containing dielectric material, and then performing a curing process to drive out the porogen, and hence the remaining dielectric layers 32 is porous. Etch stop layers (not shown), which may be formed of silicon carbide, silicon nitride, or the like, are formed between the dielectric layers 32, and are not shown for simplicity.

A plurality of metal lines 28 and vias 29 are formed in the dielectric layers 32. The metal lines 28 at a same level are collectively referred to as a metal layer hereinafter. In accordance with some embodiments of the present disclosure, interconnect structure 26 includes a plurality of metal layers that are interconnected through vias 29. The metal lines 28 and vias 29 may be formed of copper or copper alloys, and they can also be formed of other metals. The formation process may include single damascene and dual damascene processes. In a single damascene process, a trench is first formed in one of the dielectric layers 32, followed by filling the trench with a conductive material. A planarization process such as a CMP process is then performed to remove the excess portions of the conductive material higher than the top surface of the IMD layer, leaving a metal line in the trench. In a dual damascene process, both a trench and a via opening are formed in an IMD layer, with the via opening underlying and in spatial communication with the trench. The conductive material is then filled into the trench and the via opening to form a metal line and a via, respectively. The conductive material may include a diffusion barrier layer lining the trench and the via and a copper-containing metallic material over the diffusion barrier layer. The diffusion barrier layer may include titanium, titanium nitride, tantalum, tantalum nitride, or the like.

Then, a surface dielectric layer 34 is formed of a non-low-k dielectric material such as silicon oxide. The surface dielectric layer 34 is alternatively referred to as a passivation layer since it has the function of isolating the underlying low-k dielectric layers (if any) from the adverse effect of detrimental chemicals and moisture. The surface dielectric layer 34 may also have a composite structure including more than one layer, which may be formed of silicon oxide, silicon nitride, Undoped Silicate Glass (USG), or the like. Interposer dies 110 may also include metal pads underlying the surface dielectric layer 34, and the metal pads may include aluminum or aluminum copper pads, Post-Passivation Interconnect (PPI), or the like, which are not shown for simplicity.

Then, a plurality of bond pads 36A and 36B, which are also collectively and individually referred to the bond pads 36, are formed in the surface dielectric layer 34. In accordance with some embodiments of the present disclosure, the bond pads 36A and 36B are formed through a single damascene process, and may also include barrier layers and a copper-containing material formed over the barrier layers. In accordance with alternative embodiments of the present disclosure, the bond pads 36A and 36B are formed through a dual damascene process. Some of the bond pads 36A may be electrically coupled to other bond pads 36A and 36B through the metal lines 28 and vias 29. In accordance with some embodiments of the present disclosure, each of the bond pads 36A and bond pads 36B is electrically connected to at least one (or more) of other bond pads 36A and 36B through metal lines 28 and vias 29, and none of the bond pads 36A and 36B is electrically disconnected to all other bond pads 36A and 36B.

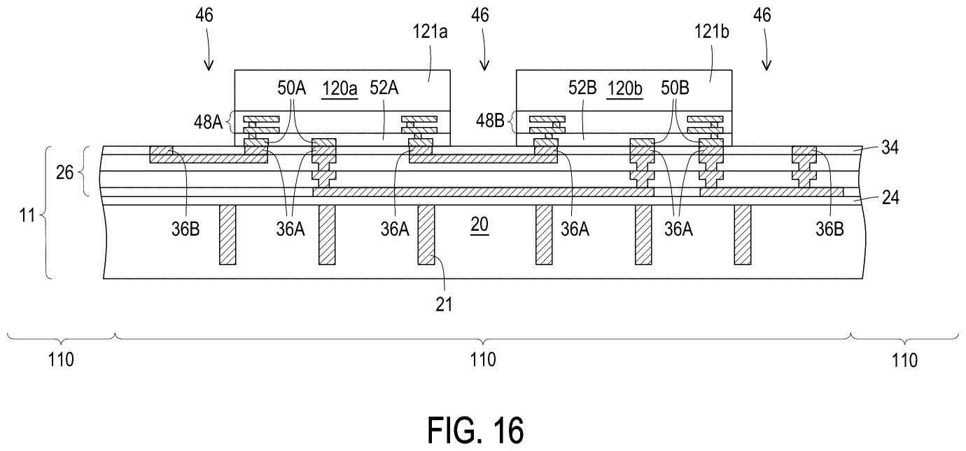

Next, referring to FIG. 16, at least one device die is bonded to the wafer 11. In the present embodiment, a plurality of device dies 120a and 120b are bonded to the wafer 11, as shown in FIG. 16, and the number of the device dies is not limited thereto. In some embodiments, the device dies 120a and 120b may be a single System on a Chip (SoC) die, multiple SoC stacked dies, or the like. One or each of the device dies 120a and 120b may also be a Central Processing Unit (CPU) die, a Micro Control Unit (MCU) die, an input-output (IO) die, a BaseBand (BB) die, or an Application processor (AP) die. The device dies 120a and 120b may be the same type or different types of dies selected from the above-listed types. In one embodiment, one of the device dies 120a and 120b may be a memory die such as Dynamic Random Access Memory (DRAM) dies or Static Random Access Memory (SRAM) dies. The device dies 120a and 120b in combination function as a package.

The device dies 120a and 120b include substrates 121a and 121b, respectively, which may be semiconductor substrates such as silicon substrates. In accordance with some embodiments, the substrates 121a and 121b are also referred to as semiconductor substrates 121a and 121b. In accordance with some embodiments of the present disclosure, the device dies 120a and 120b may be free from through silicon vias (TSVs) therein. Also, the device dies 120a and 120b include interconnect structures 48A and 48B, respectively, for connecting to the active devices and passive devices in the device dies 120a and 120b. The interconnect structures 48A and 48B include metal lines and vias, which are illustrated schematically. In some embodiments, the substrates 121a and 121b may be free from through-vias therein. Accordingly, all external electrical connections of the device dies 120a and 120b are made through the bond pads 50A and 50B.

In some embodiments, the device die 120a includes a plurality of bond pads 50A and dielectric layer 52A at the illustrated bottom surface. The bottom surfaces of bond pads 50A are coplanar with the bottom surface of dielectric layer 52A. Similarly, the device die 120b includes a plurality of bond pads 50B and dielectric layer 52B at the illustrated bottom surface. The bottom surfaces of the bond pads 50B are coplanar with the bottom surface of dielectric layer 52B.

The bonding of the device dies 120a and 120b to wafer 11 may be achieved through hybrid bonding. For example, the bond pads 50A and 50B are bonded to the bond pads 36A through direct metal bonding (i.e., metal-to-metal direct bonding). In accordance with some embodiments of the present disclosure, the metal-to-metal direct bonding is copper-to-copper direct bonding. Furthermore, the dielectric layers 52A and 52B are bonded to the surface dielectric layer 34, for example, with fusion bonds (which may include Si—O—Si bonds) generated.

To achieve the hybrid bonding, the device dies 120a and 120b are first pre-bonded to the surface dielectric layer 34 and the bond pads 36A by lightly pressing the device dies 120a and 120b against the interposer die 110. Although two device dies 120a and 120b are illustrated, the hybrid bonding may be performed at wafer level, and a plurality of device die groups identical to the illustrated die group including device dies 120a and 120b is pre-bonded, and arranged as rows and columns.

After all device dies 120a and 120b are pre-bonded, an anneal process is performed to cause the inter-diffusion of the metals in the bond pads 36A and the corresponding overlying bond pads 50A and 50B. The annealing temperature may be in the range between about 200° C. and about 400° C., and may be in the range between about 300° C. and about 400° C. in accordance with some embodiments. The annealing time is in the range between about 1.5 hours and about 3.0 hours, and may be in the range between about 1.5 hours and about 2.5 hours in accordance with some embodiments. Through the hybrid bonding, the bond pads 50A and 50B are bonded to the corresponding bond pads 36A through direct metal bonding caused by metal inter-diffusion.

The surface dielectric layer 34 is also bonded to dielectric layers 52A and 52B, with bonds formed therebetween. For example, the atoms (such as oxygen atoms) in one of the surface dielectric layer 34 and the dielectric layers 52A/52B form chemical or covalence bonds with the atoms (such as silicon atoms) in the other one of the surface dielectric layers 34 and the dielectric layer 52A/52B. The resulting bonds between the surface dielectric layers 34 and the dielectric layer 52A/52B are dielectric-to-dielectric bonds. The bond pads 50A and 50B may have sizes greater than, equal to, or smaller than, the sizes of the respective bond pads 36A. The gaps 46 are left between neighboring device dies 120a and 120b.

Further referring to FIG. 16, a backside grinding may be performed to thin the device dies 120a and 120b, for example, to a thickness between about 15 μm and about 30 μm. Through the thinning of the device dies 120a and 120b, the aspect ratio of gaps 46 between neighboring device dies 120a and 120b is reduced. Otherwise, the gap-filling may be difficult due to the otherwise high aspect ratio of gaps 46. In accordance with other embodiments in which the aspect ratio of gaps 46 is not too high for gap filling, the backside grinding is skipped.

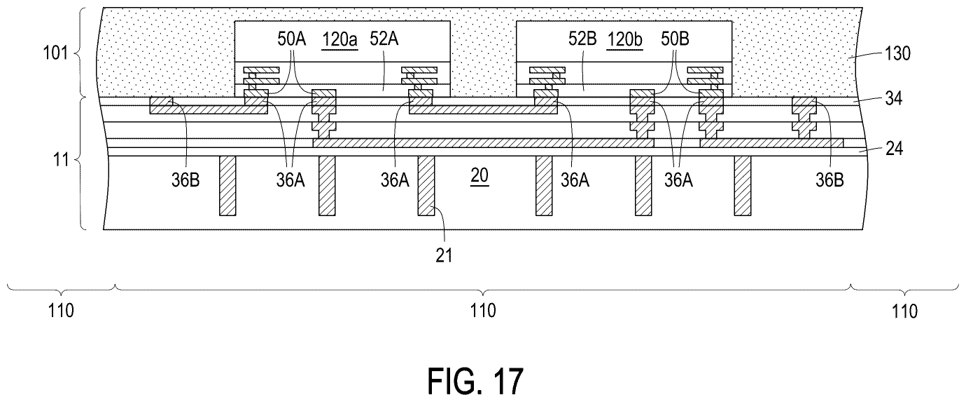

Then, referring to FIG. 17, in accordance with some embodiments of the present disclosure, an encapsulating material 130 is formed over the wafer 11. The encapsulating material 130 at least laterally encapsulates the device dies 120a and 120b. The encapsulating material 130 includes dielectric material, which may be deposited using a conformal deposition method such as Atomic Layer Deposition (ALD) or Chemical Vapor Deposition (CVD), or a non-conformal deposition method such as High-Density Plasma Chemical Vapor Deposition (HDPCVD), Flowable Chemical Vapor Deposition (CVD), spin-on coating, or the like.

In some embodiments, the encapsulating material 130 may be formed of an inorganic dielectric material. In accordance with some embodiments of the present disclosure, the encapsulating material 130 includes an oxide such as silicon oxide, which may be formed of TEOS, while other dielectric materials such as silicon carbide, silicon oxynitride, silicon oxy-carbo-nitride, or the like may also be used. The encapsulating material 130 fully fills gaps 46 (FIG. 16), and further includes some portions overlapping device dies 120a and 120b. The encapsulating material 130 may be formed of a non-conformal formation method or a conformal formation method.

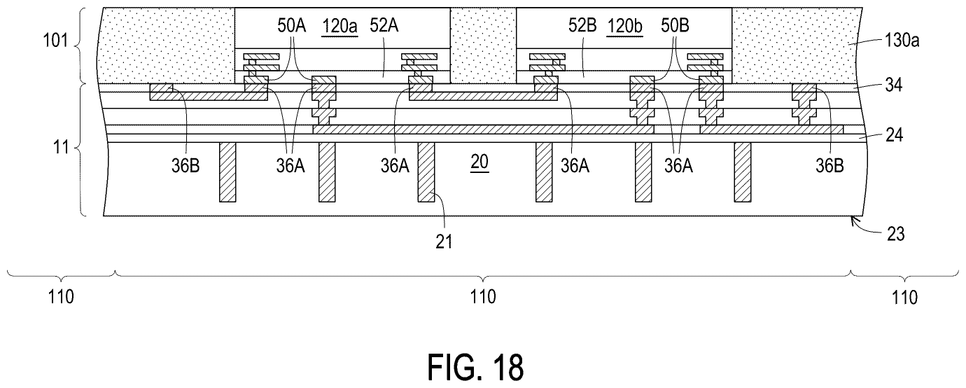

Then, referring to FIG. 18, a planarization process such as a CMP process or a mechanical grinding process is performed to remove the excess portions of the encapsulating material 130. In accordance with some embodiments of the present disclosure, the planarization is stopped when there is a layer of the encapsulating material 130 overlapping the device dies 120a and 120b. As a result, after the planarization process, the substrates 121a of the device die 120a and the substrate 121b of the device die 120b are exposed, and the exposed back surfaces of the device dies 120a and 120b are substantially coplanar with the top surface of the encapsulating material 130. At the time, a reconstructed wafer 101 over the wafer 11 is formed.

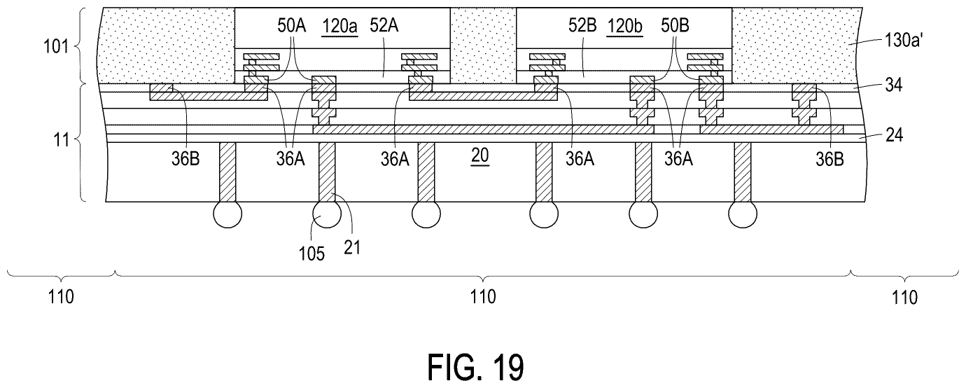

Then, referring to FIG. 18 and FIG. 19, a thinning process is performed on a back side 23 of the substrate 20 to thin the substrate 20 until the through vias 21 are exposed. In detail, the resulting structure of FIG. 18 may be flipped over to prepare for the formation of the back side 23 of the wafer 11. Although not shown, the structure may be placed on a carrier or support structure for the process of FIG. 19. The thinning process may include an etching process, a grinding process, the like, or a combination thereof.

A redistribution structure (not shown) may be formed on the back side 23 of the substrate 20, and is used to electrically connect the through vias 21 together and/or to external devices. The redistribution structure includes one or more dielectric layers and metallization patterns in the one or more dielectric layers. The metallization patterns may comprise vias and/or traces to interconnect the through vias 21 together and/or to an external device. The metallization patterns are sometimes referred to as Redistribution Lines (RDLs). The dielectric layers may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. The metallization patterns may be formed in the dielectric layer, for example, by using photolithography techniques to deposit and pattern a photoresist material on the dielectric layer to expose portions of the dielectric layer that are to become the metallization pattern.

In FIG. 19, a plurality of conductive connectors 105 are formed over the redistribution structure and are electrically coupled to the through vias 21. In some embodiments, the metallization patterns include UBMs. In the illustrated embodiment, the pads are formed in openings of the dielectric layers of the redistribution structure. In another embodiment, the pads (UBMs) can extend through an opening of a dielectric layer of the redistribution structure and also extend across the top surface of the redistribution structure.

In some embodiments, the conductive connectors 105 are solder balls and/or bumps, such as ball grid array (BGA) balls, C4 micro bumps, ENIG formed bumps, ENEPIG formed bumps, or the like. The conductive connectors 105 may include a conductive material such as solder, copper, aluminum, gold, nickel, silver, palladium, tin, the like, or a combination thereof. In some embodiments, the conductive connectors 105 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 105 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 105. The metal cap layer may include nickel, tin, tin-lead, gold, silver, palladium, indium, nickel-palladium-gold, nickel-gold, the like, or a combination thereof and may be formed by a plating process. The conductive connectors 105 may be used to bond to an additional electrical component, which may be a semiconductor substrate, a package substrate, a Printed Circuit Board (PCB), or the like (see substrate 200 in FIG. 21).

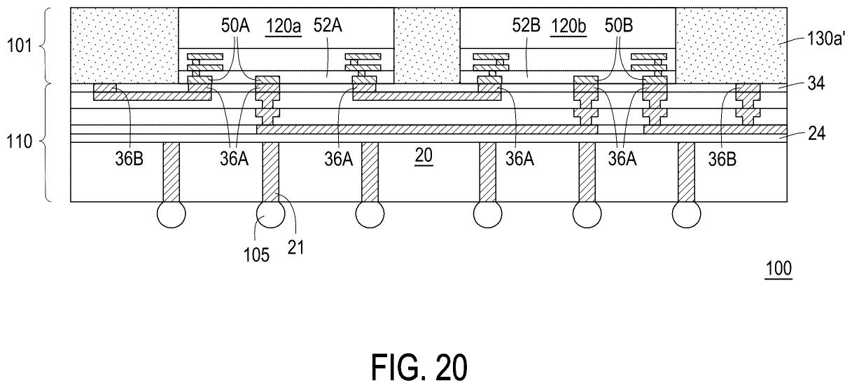

Throughout the description, the structure shown in FIG. 19 is referred to as composite wafer, which includes a reconstructed wafer 101 bonded over the wafer 11. Then, referring to FIG. 20, a singulation (die-saw) process is performed on composite wafer shown in FIG. 19 to separate the composite wafer into a plurality of package structures 100. One of the package structures 100 is illustrated in FIG. 20. In some embodiments, the package structure 100 is a die stack structure, which includes a lower die 110, and an upper die 101 stacked over and bonded to the lower die 110. The singulation process may include sawing, dicing, or the like. To be more specific, the singulation process is performed on the encapsulating material 130 and the wafer 11 to separate the composite wafer into a plurality of package structures 100. After the singulation process, the lower die 110 is singulated from the interposer wafer 11 to be functioned as an interposer, and the upper die 101 is singulated from the reconstructed wafer 101 and the device dies 120a and 120b in the upper die 101 is bonded to the lower die 110 through hybrid bonding. That is, the device dies 120a and 120b of the upper die 101 includes a plurality of upper pads 50A and 50B are in direct contact (bonding) with a plurality of lower pads 36A and 36B of the lower die 110 respectively. In the embodiment, the upper die 101 includes the device die 120a and 120b encapsulated by the encapsulating material 130. In other embodiment, the lower die 110 and the upper die 101 may both be device dies and directly bonded to the each other through hybrid bonding. The disclosure is not limited thereto.

FIG. 21 illustrates the bonding of the package structure 100 onto a substrate 200. Referring to FIG. 20 and FIG. 21, the conductive connectors 105 are aligned to, and are put against, the bond pads of the substrate 200. The conductive connectors 105 may be reflowed to create a bond between the substrate 200 and the first package structure 100. The substrate 200 may include a package substrate, such as a build-up substrate including a core therein, a laminate substrate including a plurality of laminated dielectric films, a PCB, or the like. The substrate 200 may include electrical connectors (not shown), such as solder balls, opposite the component package to allow the substrate 200 to be mounted to another device. In the package structure 100, the lower die 110 is bonded to the substrate 300 through the conductive connectors 105 and a plurality of dies 120a and 120b are stacked over and bonded to the lower die 110 through, for example, hybrid bonding (e.g., fusion bonding and direct metal bonding). That is, there is no conductive connectors between the lower die 110 and upper die 101(including dies 120a and 120b), and the pads of the dies 120a and 120b are in direct contact with the pads of the lower die 110. The encapsulating material 130 is disposed over the lower die 110 and laterally encapsulating the dies 120a and 120b. An underfill material 106 may be provided between the package structure 100 and the substrate 200 and encapsulate the conductive connectors 105. Then, the processes as illustrated in FIG. 3 to FIG. 4 can be applied to the package 104 shown in FIG. 21 and form the semiconductor package.

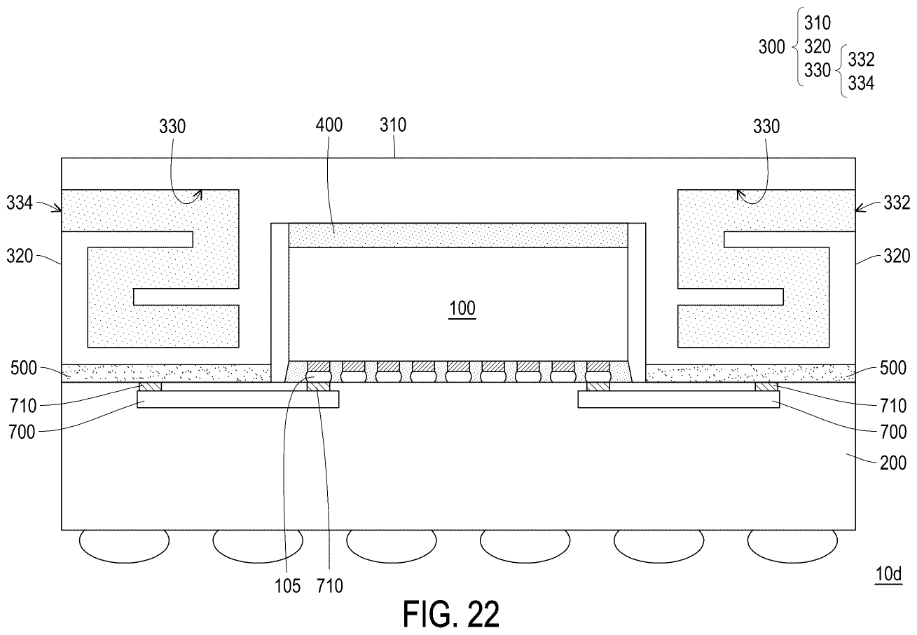

FIG. 22 illustrates a cross sectional view of the semiconductor package according to some embodiments of the present disclosure. It is noted that the semiconductor package shown in FIG. 22 contains many features same as or similar to the semiconductor package disclosed in the previous embodiments. For purpose of clarity and simplicity, detail description of same or similar features may be omitted, and the same or similar reference numbers denote the same or like components.

Referring to FIG. 22, in some embodiments, the adhesive 500 disposed between the cover structure 300 and the substrate 200 may include thermal conductive adhesive for thermally coupling the cover structure 300 and the substrate 200 and adhering the cover structure 300 to the substrate 200. The thermal conductive adhesive 500 may include a metal paste that includes (high-k) adhesive material such as epoxy with metal fillers (e.g., silver particles, copper particles) dispersed therein. The adhesive material (e.g., epoxy) may also be referred to as a solvent for the metal fillers. In some embodiments, the thermal conductive adhesive 500 includes an electrically conductive material (e.g., copper, aluminum, silver) that has good thermal conductivity (e.g., larger than 15 watts per meter-kelvin (W/(m·k))) and high heat capacity (e.g., about 1 joules per gram per degree Celsius (J/(g° C.)) or larger). The thermal conductive adhesive 500 may be formed by depositing, CVD, sputtering, plating, dispensing, jetting, printing, or the like. In some embodiments, the thermal conductive adhesive 500 is a dielectric material having good thermal conductivity (e.g., larger than 15 W/(m·k)) and high heat capacity (e.g., about 1 J/(g° C.) or larger). In the various embodiments discussion herein, silver paste may be used as the thermal conductive adhesive 500. With the understanding that besides metal paste, any suitable thermal conductive adhesive may be used without departing from the spirit of the present disclosure.

In some embodiments, the semiconductor package 10d may further include a thermal interconnect device 700 that is embedded in the substrate 200 and thermally coupled to the package structure 100 and the ring portion 320. In some embodiments, the thermal interconnect device 700 overlap with the package structure 100 and the ring portion 320 from a top view. The thermal interconnect device 700 is embedded in the substrate 200 during the formation of the substrate 200 and is bonded to and thermally coupled to the cover structure 300 and the package structure 100 through a plurality of thermal conductive connectors 710. The thermal interconnect device 700 shown in FIG. 22 has thermal conductive connectors 710 formed on a single side of the thermal interconnect device 700, but in some embodiments, a thermal interconnect device 700 may have thermal conductive connectors 710 formed on both sides.

In some embodiments, the thermal conductive connectors 710 include metal pads or metal pillars (such as copper pillars). The thermal conductive connectors 710 may include a conductive material such as solder, copper, aluminum, gold, nickel, silver, palladium, tin, the like, or a combination thereof. In some embodiments, the metal pillars may be solder-free and/or have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The thermal interconnect device 700 may be formed using applicable manufacturing processes. The thermal interconnect device 700 may include a substrate, which is, for example, a semiconductor substrate, such as silicon, which may be doped or undoped, and which may be a silicon wafer, or the like. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the thermal interconnect device 700 is embedded in the substrate 200 to provide additional heat dissipation pathways from the package structure 100. For example, heat may flow from the package structure 100 to the cover structure 300 through the thermal interconnect device 700, and subsequently be drawn by the cooling fluid in the fluid channel 330. In some embodiments, the thermal interconnect device 700 may include a suitable material having a high thermal conductivity, such as Cu, Al, NiCo, AlSiC, alloys thereof, combination thereof, and/or the like. The thermal interconnect device 700 may also include a graphite sheet, a nano-sheet based composite, a dummy silicon die, one or more silicon bars or blocks, and/or the like. In some embodiments, the thermal interconnect device 700 is electrically insulated from the package structure 100. In other embodiments, the thermal interconnect device 700 may be electrically connected to a ground electrode of the package structure 100.

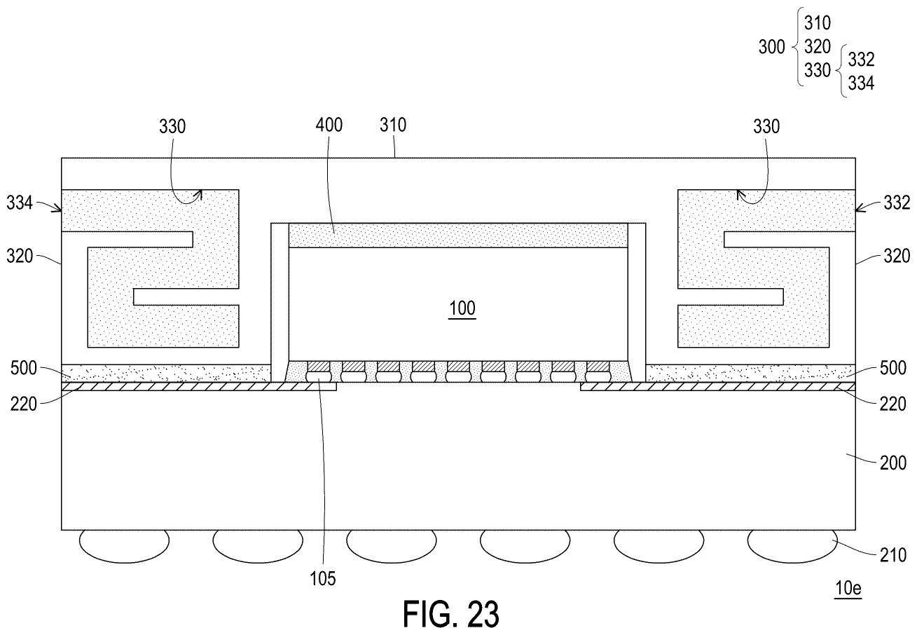

FIG. 23 illustrates a cross sectional view of the semiconductor package according to some embodiments of the present disclosure. It is noted that the semiconductor package shown in FIG. 23 contains many features same as or similar to the semiconductor package disclosed in the previous embodiments. For purpose of clarity and simplicity, detail description of same or similar features may be omitted, and the same or similar reference numbers denote the same or like components.

Referring to FIG. 23, in the embodiments, the adhesive 500 disposed between the cover structure 300 and the substrate 200 may include thermal conductive adhesive for thermally coupling the cover structure 300 and the substrate 200 and adhering the cover structure 300 to the substrate 200. The thermal conductive adhesive 500 may include a metal paste that includes (high-k) adhesive material such as epoxy with metal fillers (e.g., silver particles, copper particles) dispersed therein. The adhesive material (e.g., epoxy) may also be referred to as a solvent for the metal fillers. In some embodiments, the thermal conductive adhesive 500 includes an electrically conductive material (e.g., copper, aluminum, silver) that has good thermal conductivity and high heat capacity. The thermal conductive adhesive 500 may be formed by depositing, CVD, sputtering, plating, dispensing, jetting, printing, or the like. In some embodiments, the thermal conductive adhesive 500 is a dielectric material having good thermal conductivity and high heat capacity. In the various embodiments discussion herein, silver paste may be used as the thermal conductive adhesive 500. With the understanding that besides metal paste, any suitable thermal conductive adhesive may be used without departing from the spirit of the present disclosure.

In some embodiments, the substrate 200 may further include a thermal trace 220 connecting between the package structure 100 and the ring portion 320 of the cover structure 300. The thermal trace 220 is thermally coupled to but electrically insulated from the package structure 100. In an alternative embodiment, the thermal interconnect device 700 may be electrically connected to a ground electrode of the package structure 100. In some embodiments, the thermal trace 220 may be formed by the same method and material as the rest of the redistribution circuits in the substrate 200. The thermal trace 220 is electrically insulated from functional vias and circuits of the substrate 200 and may be connected to thermal vias in the substrate 200. In some embodiments, the thermal trace 220 may be a wide metal, which means a solid metal pad and the thermal trace 220 may overlap with the package structure 100 and the ring portion 320 from a top view. In some embodiments, the thermal trace 220 may be electrically connected to a ground of the substrate 200 and/or a ground of the package structure 100. The thermal trace 220 in the substrate 200 provides additional heat dissipation pathways from the package structure 100. For example, heat may flow from the package structure 100 to the cover structure 300 through the thermal trace 220, and subsequently be drawn by the cooling fluid in the fluid channel 330 of the cover structure 300.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a package structure disposed over the substrate, and a cover structure including a ring portion disposed over the substrate and laterally surrounding the package structure, a lid portion covering and thermally coupled to the package structure, and a fluid channel passing through the ring portion and laterally surrounding the package structure. In one embodiment, the cover structure comprises an inlet in fluid communication with the fluid channel for cooling fluid to flow into the fluid channel and an outlet in fluid communication with the fluid channel for the cooling fluid to flow out of the fluid channel. In one embodiment, the inlet is located on a first outer side surface of the cover structure. In one embodiment, the outlet is located on a second outer side surface of the cover structure, and the first outer side surface and the second outer side surface are adjacent to each other. In one embodiment, the outlet is located on a second outer side surface of the cover structure, and the first outer side surface and the second outer side surface are opposite to each other. In one embodiment, the fluid channel does not overlap with the package structure from a top view. In one embodiment, the semiconductor package further includes a thermal interconnect device embedded in the substrate and thermally coupled to the package structure and the ring portion. In one embodiment, the thermal interconnect device overlap with the package structure and the ring portion from a top view. In one embodiment, the substrate further comprises a thermal trace connecting between the package structure and the ring portion and electrically insulated from the package structure.

In accordance with some embodiments of the disclosure, a semiconductor package includes a substrate, a package structure disposed over the substrate, and a cover structure disposed over the substrate and configured to surround and thermally coupled to the package structure, wherein the cover structure includes a fluid channel extending through the cover structure, an inlet and an outlet located on at least one vertical side surface of the cover structure and in fluid communication with the fluid channel. In one embodiment, the inlet and the outlet are located at an upper portion of the vertical side surface of the cover structure away from the substrate. In one embodiment, the fluid channel is extended from an upper portion of a side wall of the cover structure to a lower portion of the side wall of the cover structure in a zigzag manner. In one embodiment, a thickness of the side wall of the cover structure is substantially equal to or greater than 8 mm. In one embodiment, the semiconductor package further includes a thermal interface material disposed between the package structure and the cover structure. In one embodiment, the semiconductor package further includes a thermal conductive adhesive disposed between the cover structure and the substrate for thermally coupling the cover structure and the substrate and adhering the cover structure to the substrate. In one embodiment, the fluid channel does not overlap with the package structure from a top view.

In accordance with some embodiments of the disclosure, a manufacturing method of a semiconductor package includes: providing a package structure over a substrate; providing a thermal interface material over the package structure; and bonding a cover structure over the substrate through an adhesive, wherein the cover structure is in contact with the thermal interface material and includes a fluid channel passing through a side wall of the cover structure and laterally surrounding the package structure. In one embodiment, providing the package structure over the substrate further includes: bonding a device die over an interconnect structure; encapsulating the device die with an encapsulating material to form a package structure; and bonding the package structure over the substrate through a plurality of conductive bumps. In one embodiment, the cover structure comprises an inlet and an outlet located on an outer side surface of the side wall of the cover structure and in fluid communication with the fluid channel. In one embodiment, the method further includes: connecting a first pipe to the inlet for providing cooling fluid from the first pipe to the fluid channel; and connecting a second pipe to the outlet for the cooling fluid in the fluid channel to flow out of the fluid channel and flow to the second pipe.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a package structure disposed over the substrate; and
a cover structure comprising a ring portion disposed over the substrate and laterally surrounding the package structure, a lid portion covering and thermally coupled to the package structure, and a fluid channel passing through the ring portion and laterally surrounding the package structure.

2. The semiconductor package as claimed in claim 1, wherein the cover structure comprises an inlet in fluid communication with the fluid channel for cooling fluid to flow into the fluid channel and an outlet in fluid communication with the fluid channel for the cooling fluid to flow out of the fluid channel.

3. The semiconductor package as claimed in claim 2, wherein the inlet is located on a first outer side surface of the cover structure.

4. The semiconductor package as claimed in claim 3, wherein the outlet is located on a second outer side surface of the cover structure, and the first outer side surface and the second outer side surface are adjacent to each other.

5. The semiconductor package as claimed in claim 3, wherein the outlet is located on a second outer side surface of the cover structure, and the first outer side surface and the second outer side surface are opposite to each other.

6. The semiconductor package as claimed in claim 1, wherein the fluid channel does not overlap with the package structure from a top view.

7. The semiconductor package as claimed in claim 1, further comprising a thermal interconnect device embedded in the substrate and thermally coupled to the package structure and the ring portion.

8. The semiconductor package as claimed in claim 7, wherein the thermal interconnect device overlap with the package structure and the ring portion from a top view.

9. The semiconductor package as claimed in claim 1, wherein the substrate further comprises a thermal trace connecting between the package structure and the ring portion and electrically insulated from the package structure.

10. A semiconductor package, comprising:
a substrate;
a package structure disposed over the substrate; and
a cover structure disposed over the substrate and configured to surround and thermally coupled to the package structure, wherein the cover structure comprises a fluid channel extending through the cover structure, an inlet and an outlet located on at least one vertical side surface of the cover structure and in fluid communication with the fluid channel.

11. The semiconductor package as claimed in claim 10, wherein the inlet and the outlet are located at an upper portion of the vertical side surface of the cover structure away from the substrate.

12. The semiconductor package as claimed in claim 10, wherein the fluid channel is extended from an upper portion of a side wall of the cover structure to a lower portion of the side wall of the cover structure in a zigzag manner.

13. The semiconductor package as claimed in claim 12, wherein a thickness of the side wall of the cover structure is substantially equal to or greater than 8 mm.

14. The semiconductor package as claimed in claim 10, further comprising a thermal interface material disposed between the package structure and the cover structure.

15. The semiconductor package as claimed in claim 10, further comprising a thermal conductive adhesive disposed between the cover structure and the substrate for thermally coupling the cover structure and the substrate and adhering the cover structure to the substrate.

16. The semiconductor package as claimed in claim 10, wherein the fluid channel does not overlap with the package structure from a top view.

17. A manufacturing method of a semiconductor package, comprising:
providing a package structure over a substrate;
providing a thermal interface material over the package structure; and
bonding a cover structure over the substrate through an adhesive, wherein the cover structure is in contact with the thermal interface material and comprises a fluid channel passing through a side wall of the cover structure and laterally surrounding the package structure.

18. The manufacturing method of the semiconductor package as claimed in claim 17, wherein providing the package structure over the substrate further comprising:
bonding a device die over an interconnect structure;
encapsulating the device die with an encapsulating material to form a package structure; and
bonding the package structure over the substrate through a plurality of conductive bumps.

19. The manufacturing method of the semiconductor package as claimed in claim 17, wherein the cover structure comprises an inlet and an outlet located on an outer side surface of the side wall of the cover structure and in fluid communication with the fluid channel.

20. The manufacturing method of the semiconductor package as claimed in claim 19, further comprising:
connecting a first pipe to the inlet for providing cooling fluid from the first pipe to the fluid channel; and
connecting a second pipe to the outlet for the cooling fluid in the fluid channel to flow out of the fluid channel and flow to the second pipe.
